(19) United States
(12) Patent Application Publication
(10) Pub. No.: US 2024/0371594 A1
(43) Pub. Date: Nov. 7, 2024

(54) AIR-COOLED DEPRESSED COLLECTORS AND METHODS

(71) Applicant: Elve Inc., Davis, CA (US)

(72) Inventors: Danny Chan, San Mateo, CA (US); Michelle Gonzalez, Woodland, CA (US); Diana Gamzina Daugherty, Davis, CA (US)

(73) Assignee: Elve Inc., Davis, CA (US)

(21) Appl. No.: 18/657,184

(22) Filed: May 7, 2024

Related U.S. Application Data
(60) Provisional application No. 63/464,598, filed on May 7, 2023.

(51) Int. Cl. H01J 23/033; H01J 23/027; H05K 7/20

(52) U.S. Cl. CPC H01J 23/033; H01J 23/0275; H05K 7/20154

(57) ABSTRACT

A depressed collector, comprises an insulator body; a plurality of serial electrodes, each serial electrode having a serial electrode receptor portion inside the insulator body and having a serial electrode thermal fin portion passing through and extending outside the insulator body; and a terminal electrode having a terminal electrode receptor portion inside the insulator body and having a terminal electrode thermal fin portion passing through and extending outside the insulator body.

### PRIORITY CLAIM

This application claims benefit of and hereby incorporates by reference provisional patent application Ser. No. 63/464,598, entitled “Air Cooled Depressed Collector Design,” filed on May 7, 2023, by inventors Danny Chan, Michelle Gonzalez and Diana Gamzina Daugherty.

### TECHNICAL FIELD

This invention relates generally to electron beam devices, and more particularly provides an air-cooled depressed collector for use in electron beam devices.

### BACKGROUND

Electron beam devices, such as traveling wave tubes, are known for generating and amplifying high frequency electromagnetic waves. In an electron beam device, an electron gun generates and sends an electron beam into an interaction structure, e.g., a structure in which an electromagnetic wave is also propagating. The interaction structure often includes an electron beam tunnel supporting a vacuum medium. A variety of interaction mechanisms in the interaction structure cause a portion of the energy of the electron beam to transfer to the electromagnetic wave in order to cause desired effects, e.g., amplification of the electromagnetic wave. After exiting the interaction structure, the spent electrons of the electron beam pass into a collector structure that decelerates and captures the spent electrons in order to recover a portion of their remaining energy. Electrodes disposed within the collector structure are used to try to collect the remaining energy of the spent electrons in order to return power to the source powering the electron beam device. Accordingly, collector structures increase the overall direct current (DC) to radio-frequency (RF) conversion efficiency of electron beam devices, such as travelling wave tubes. However, not all beam energy is recovered. Unrecovered beam energy is transformed into heat within the collector structure, which without sufficient cooling can cause a variety of adverse effects.

Depressed collectors are commonly used in electron beam devices to improve the efficiency of energy conversion to the electromagnetic wave and thus reduce heat transferred to the collector structure. After the interaction between the electron beam and the electromagnetic wave, the spent electrons have an energy spread. In other words, the electrons are traveling at different velocities. Depressed collectors enable matching of the electronic potentials of the spent electrons of the electron beam to increase the efficiency of recovery of the remaining energy. The lowest-energy electrons are collected in a first, least-depressed stage electrode of the depressed collector, and higher energy electrons progress to a second or subsequent stage electrode of the depressed collector. As a result, only the mismatch between the actual electron energy and the electronic potential of the individual collector electrode is converted to heat. Depressed collectors have been demonstrated to convert the electron beam energy back to electronic current with efficiencies as high as 99%.

Despite the high efficiency, even depressed collectors generate heat that needs to be dissipated. To avoid overheating of the depressed collector, heat may be transferred out of the depressed collector and dissipated to the external environment. This is especially challenging because the electrodes of the depressed collector operate at high voltage potentials and hence need to be electrically isolated from surrounding ground potentials where most cooling systems reside. Various heat compensating devices have been deployed in the past, including: (1) Conduction-cooled collector where an insulator ceramic is utilized as an electrically insulating thermal path to remove generated heat; (2) Radiation cooled collector (most commonly deployed in space applications), where there is a conduction path to a grounded shell, and the grounded shell is exposed to the external environment to radiate; (3) Liquid cooled collector, where the electrodes are cooled with electrically non-conductive (or minimally-conductive with a long enough transport path) circulating liquid to remove the heat while maintaining electrical isolation. These heat compensating devices are not without drawbacks. Accordingly, an improved cooling system is needed for depressed collectors.

### SUMMARY

In some embodiments, the present invention provides an air-cooled (or other gas-cooled) depressed collector that includes extended individual collector electrodes, which serve as thermal fins while still operating at high voltage. In some embodiments, the air-cooled depressed collector includes a heat sink with supplemental thermal fins to provide supplemental cooling effects. In some embodiments, airflow may be circulated over the electrode thermal fins of the collector electrodes and/or over the supplemental thermal fins of the heat sink to enhance heat removal. In some embodiments, airflow may be directed around the circumference of the depressed collector to enhance airflow exposure to the heat generating collector electrodes and/or around the circumference of the heat sink to enhance airflow exposure to the heat sink. In some embodiments the air-cooled depressed collector includes electrical isolation in a package.

In some embodiments, the present invention provides a depressed collector, comprising an insulator body; a plurality of serial electrodes, each serial electrode having a serial electrode receptor portion inside the insulator body and having a serial electrode thermal fin portion passing through and extending outside the insulator body; and a terminal electrode having a terminal electrode receptor portion inside the insulator body and having a terminal electrode thermal fin portion passing through and extending outside the insulator body.

The insulator body may be made of ceramic material. The serial electrode thermal fin portion of each serial electrode of the plurality of serial electrodes may have substantially identical dimensions. The terminal electrode thermal fin portion may have substantially identical dimensions to the serial electrode thermal fin portion of each serial electrode. The serial electrode thermal fin portions of the plurality of serial electrodes may have substantially identical spacing. The terminal electrode thermal fin portion may have the substantially identical spacing from one of the serial electrode thermal fin portions of the plurality of serial electrodes. The terminal electrode receptor portion may be a terminal electrode rear receptor portion, and the terminal electrode may further include a terminal electrode forward receptor portion. The depressed collector may further comprise a heat sink attached to the terminal electrode. The heat sink may have a heat sink surface mounted flush to a rear wall of the terminal electrode. The heat sink may include heat sink thermal fins extending outward. The heat sink thermal fins may have substantially identical geometry. The heat sink thermal fins may have substantially identical spacing. The depressed collector may further comprise a gateway coupled to the insulator body and having a gateway opening to allow an electron beam from an interaction structure to enter the depressed collector. The gateway may be maintained at ground potential, and each of the plurality of serial electrodes and the terminal electrode may be maintained at a high voltage potential. The plurality of serial electrodes and the terminal electrode may be maintained at respectively increasing voltage potentials. The insulator body, the plurality of serial electrodes and the terminal electrode may assist in forming an enclosure. The enclosure may maintain a vacuum environment. The plurality of serial electrodes and the terminal electrode may comprise metal. Each of the plurality of serial electrodes and the terminal electrode may be maintained at a high voltage potential, and the plurality of serial electrodes and the terminal electrode may be maintained at a distance from a ground plane to avoid ionization. At least one serial electrode of the plurality of serial electrodes may include a plurality of thermal fin portions extending outside the insulator body.

In some embodiments, the present invention may provide a method comprising providing a depressed collector including an insulator body; a plurality of serial electrodes, each serial electrode having a serial electrode receptor portion inside the insulator body and having a serial electrode thermal fin portion passing through and extending outside the insulator body; and a terminal electrode having a terminal electrode receptor portion inside the insulator body and having a terminal electrode thermal fin portion passing through and extending outside the insulator body; and passing a gas over the serial electrode thermal fin portions of the plurality of serial electrodes.

The depressed collector may further include a heat sink attached to the terminal electrode, the heat sink having heat sink thermal fins extending outward, and the passing the gas over the serial electrode thermal fin portions of the plurality of serial electrodes may include passing the gas over the heat sink thermal fins. The gas may be air. Each of the plurality of serial electrodes and the terminal electrode may be maintained at a high voltage potential, and the plurality of serial electrodes and the terminal electrode may be maintained at a distance from a ground plane to avoid ionization.

### BRIEF DESCRIPTION OF THE DRAWINGS

FIG. 1 is a cross-sectional side view (y-z plane) of an air-cooled depressed collector, in accordance with some embodiments of the present invention.

FIG. 2 is a cross-sectional view along the propagation direction of the electron beam (x-y plane) of the air-cooled depressed collector of FIG. 1, in accordance with some embodiments of the present invention.

FIG. 3 illustrates an example rectangular annular thermal fin design, in accordance with some embodiments of the present invention.

FIG. 4 illustrates an array of rectangular annular fins, in accordance with some embodiments of the present invention.

### DETAILED DESCRIPTION

The following description is provided to enable a person skilled in the art to make and use various embodiments of the invention. Modifications are possible. The generic principles defined herein may be applied to the disclosed and other embodiments without departing from the spirit and scope of the invention. Thus, the claims are not intended to be limited to the embodiments disclosed, but are to be accorded the widest scope consistent with the principles, features and teachings herein.

In some embodiments, the present invention provides an air-cooled (or other gas-cooled) depressed collector that includes extended individual collector electrodes, which serve as thermal fins while still operating at high voltage. In some embodiments, the air-cooled depressed collector includes a heat sink with supplemental thermal fins to provide supplemental cooling effects. In some embodiments, airflow may be circulated over the electrode thermal fins of the collector electrodes and/or over the supplemental thermal fins of the heat sink to enhance heat removal. In some embodiments, airflow may be directed around the circumference of the depressed collector to enhance airflow exposure to the heat generating collector electrodes and/or around the circumference of the heat sink to enhance airflow exposure to the heat sink. In some embodiments the air-cooled depressed collector includes electrical isolation in a package.

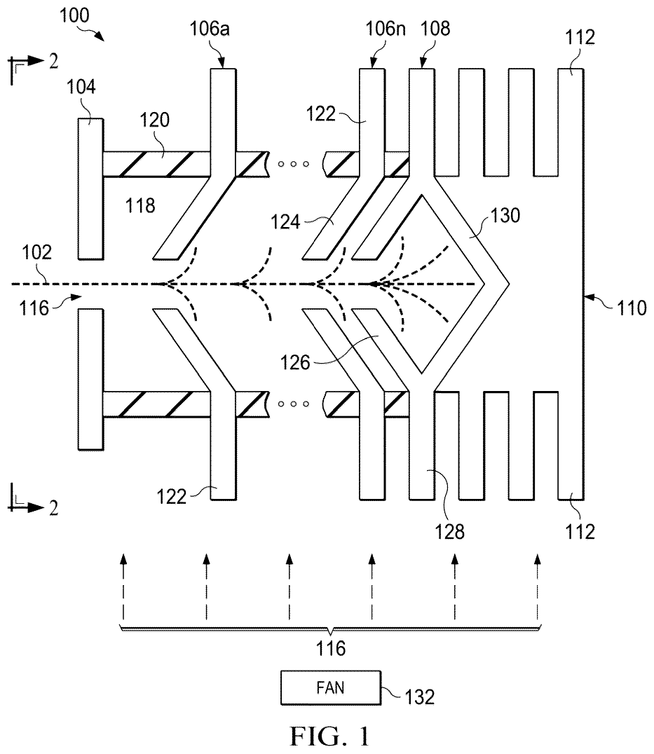

FIG. 1 is a cross-sectional side view (y-z plane) of an air-cooled depressed collector 100, in accordance with some embodiments of the present invention. Although embodiments herein are described as being air cooled, other gases may be alternatively or additionally used. The air-cooled depressed collector 100 includes a gateway 104, serial electrodes 106a-106n (collectively 106) and a terminal electrode 108, each coupled to an insulator body 120. In some embodiments, the gateway 104, serial electrodes 106, terminal electrode 108, and insulator body 120 together assist to form an enclosure 118 that, in some embodiments, maintains a vacuum environment therein. In some embodiments, the insulator body 120 is made of ceramic, and the serial electrodes 106 and terminal electrode 108 are made of metal.

Each of the gateway 104, serial electrodes 106 and terminal electrode 108 has an opening that together form an electron beam path 116 for an electron beam 102 of spent electrons coming from an interaction structure (not shown).

In some embodiments, the gateway 104 is maintained at a ground voltage, and each of the serial electrodes 106 and terminal electrode 108 are maintained at a non-zero voltage or at a variety of non-zero voltages. In some embodiments, the serial electrodes 106 and terminal electrode 108 are stacked along the direction of the beam propagation at increasing voltage potentials. That is, each electrode 106/108 of the serial electrodes 106 and terminal electrode 108 is maintained at an increasing voltage potential to attract spent electrons from the electron beam 102 according to their remaining energy. The first, least-depressed stage electrode 106a collects the spent electrons having lowest-energy. The subsequent stage serial electrodes 106 collect spent electrons having respectively increasing higher energy. The terminal electrode 108 collects any remaining spent electrons, which are likely to have the highest energy.

Each of the serial electrodes 106 includes a serial electrode receptor 124 inside the insulator body 120 and a serial electrode thermal fin 122 extending through the insulator body 120 and outside the enclosure 118. The terminal electrode 108 includes a terminal electrode forward receptor 126, a terminal electrode thermal fin 128 and a terminal electrode rear receptor 130. The terminal electrode rear receptor 130 captures all remaining electrons that were not captured by the serial electrode receptors 124 or the terminal electrode forward receptor 126. The terminal electrode rear receptor 130 will likely collect a bulk of the electron beam energy and hence require most cooling. The shape of the serial electrode receptors 124 and the terminal electrode forward receptor 126 may be designed to optimize formation of the electric fields that help guide electron trajectories towards desired locations. Angled, tapered, straight, cupped, offset, symmetric, asymmetric, and other varieties of shapes are utilized to improve electron transport likelihood towards desired locations.

In some embodiments, the serial electrode thermal fins 122 and terminal electrode thermal fin 128 may be designed to have a regular pattern, such that they are of equal geometry (width, length, height) and equal spacing from one another. In other embodiments, the serial electrode thermal fins 122 and terminal electrode thermal fin 128 may be designed to have an irregular pattern, e.g., having different geometries and/or different spacing at different distances from each other. Although FIG. 1 shows the serial electrode thermal fins 122 and the terminal electrode thermal fin 128 as having a rectangular cross-section, thermal fin shape can be straight triangular, straight parabolic, spine rectangular, spine triangular, or otherwise shaped to optimize thermal transport. Further, although each electrode 106/108 of the serial electrodes 106 and terminal electrode 108 is shown to include an individual thermal fin, one or more of the electrodes 106/108 can have extensions that split into multiple thermal fins 122 to enhance heat transport further.

In some embodiments, the air-cooled depressed collector 100 may further include a heat sink 110 coupled to the terminal electrode 108, although in other embodiments it can be coupled elsewhere. The heat sink 110 may be positioned to sit flush against the external wall of the terminal electrode rear receptor 130. The heat sink 110 may include heat sink thermal fins 112 that extend outward in a similar pattern as the serial electrode thermal fins 122 and the terminal electrode thermal fin 128. In some embodiments, the heat sink 110 is maintained at a high voltage potential.

In some embodiments, the heat sink thermal fins 112 is designed to have substantially the same (the same within design tolerances) regular pattern (geometry and/or spacing) as the serial electrode thermal fins 122 and the terminal electrode thermal fin 128. In other embodiments, the heat sink thermal fins 112 may be designed to have an irregular pattern, e.g., having different geometries and/or spacing from each other. In other embodiments, the heat sink thermal fins 112 may be designed to have a regular or irregular pattern that is different than the regular or irregular pattern of the serial electrode thermal fins 122 and the terminal electrode thermal fin 128. Although FIG. 1 shows the heat sink thermal fins 112 as having a rectangular cross-section, thermal fin shape can be straight triangular, straight parabolic, spine rectangular, spine triangular, or otherwise shaped to optimize thermal transport. Fins may be serrated to increase turbulence or not serrated.

Fin efficiency is defined as the ratio of the heat transfer to the fin to the heat transfer to an ideal fin. The thermal fins (serial electrode thermal fins 122, terminal electrode thermal fin 128 and/or heat sink thermal fins 112) can be designed using thermal fin efficiency as an optimization parameter with thermal fin geometry (e.g., height, width and/or length) and spacing being optimization variables, e.g., according to the Bessel function formula.

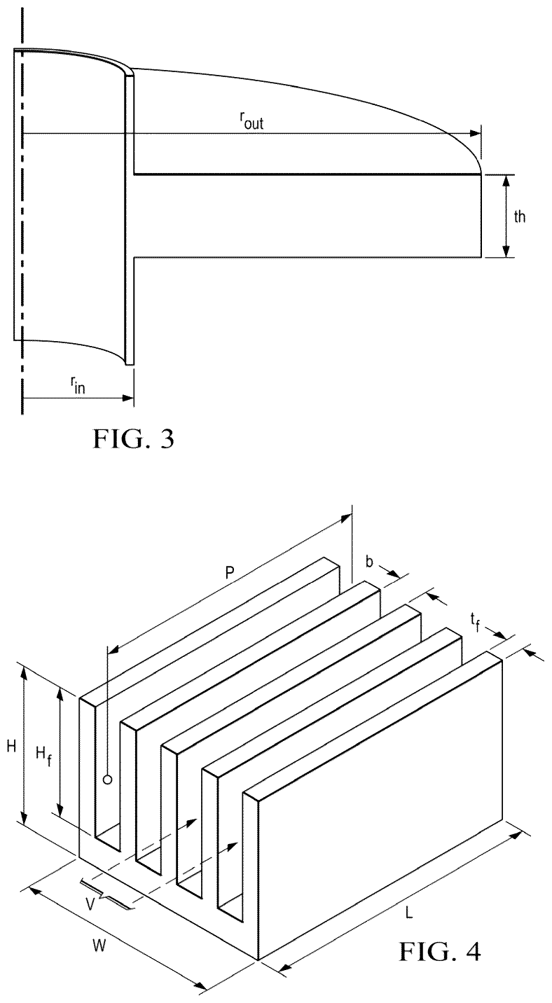

Standard equation for the thermal fin efficiency of the rectangular annular thermal fins can be utilized as an example. FIG. 3 shows an example rectangular annular thermal fin design, in accordance with some embodiments of the present invention. Below is an efficiency calculation equation to determine efficiency of a rectangular fin swept outside of the cylindrical feature providing for a simple collector with fins configuration. Thermal conductivity, k, is a material property of the fin at the operating temperature. Heat transfer coefficient, h, can vary between 1 and 1000 W/m2-K for stagnant to free to forced convection conditions in air.

$$\text{?} = 2 π ( {r}_{out}^{2} - {r}_{in}^{2} )$$

$$\text{?} = \sqrt{\frac{2 \overline{h}}{kth}} {r}_{out}$$

$$\text{?} = \sqrt{\frac{2 \overline{h}}{kth}} {r}_{in}$$

$$\text{?} = \frac{2 \text{?}}{[ {( \text{?} )}^{2} - {( \text{?} )}^{2} ]} \frac{[ \text{?} ( 1 , \text{?} ) \text{?} ( 1 , \text{?} ) - \text{?} ( 1 , \text{?} ) \text{?} ( 1 , \text{?} ) ]}{[ \text{?} ( 0 , \text{?} ) \text{?} ( 0 , \text{?} ) + \text{?} ( 0 , \text{?} ) \text{?} ( 0 , \text{?} ) ]}$$

$$\text{?} \text{indicates text missing or illegible when filed}$$

where,
r_in—inner diameter of annular disk
r_out—outer diameter of annular disk
th—thickness of annular disk
h—heat transfer coefficient
k—conductivity of fin material

Similarly, the collection of thermal fins generated by the multiple electrode stages can be analyzed for total heat transfer efficiency. The heat transfer coefficient applicable to the design can either be calculated analytically based on the overall geometry and atmospheric conditions of the flow of air (or other gas) or modeled in a finite element fluid dynamics software. As shown in FIG. 4, the thermal fins may be designed as an array with basic dimensions for fin efficiency optimization. Spacing between the fins may be determined to follow Paschen's law to ensure there is no breakdown between the thermal fins in air or creepage along the insulator body 120.

For a straight rectangular annular fin, the equations are as follows:

$${n}_{fin} = \frac{tanh ( mL )}{mL}$$

$${A}_{s , fin} = 2 WL$$

$$mL = \sqrt{\frac{2 \overline{h}}{kth}} L$$

where,
Nfin—number of fins
Asb—the base surface area in unit area=W L.
Acb—the cross section base area in unit area=(Nfin) t L.
h—the convective heat transfer in W/(m²K).

In some embodiments, a fan 132 (or other airflow generator such as a blower or stack) may generate airflow 116 to circulate over the serial electrode thermal fins 122 and the terminal electrode thermal fin 128 and/or over the heat sink thermal fins 112 to enhance heat removal. In some embodiments, the airflow 116 may be directed around the circumference of the depressed collector 100 and/or around the circumference of the heat sink 110 to enhance airflow exposure to the heat generating electrodes 106 and 108 and/or to enhance airflow exposure to the heat sink 110.

The design can apply to cylindrical or other form, symmetric or non-symmetric, designs.

In some embodiments, operation of the air-cooled depressed collector 100 relies on air as an insulating medium. Insulating properties of air depend on temperature, pressure, cleanliness, and humidity, and hence may need to be validated for operating conditions of each individual device. Regions with high voltage gradients can cause air or gas to ionize and cause ionization and as a result conduction or dielectric discharge. Paschen's law can be utilized to estimate electrical breakdown limits in air or gas operating conditions. To achieve safe operating conditions, the serial electrodes 106 and terminal electrode 108 might need to be located a proper distance away from ground potential to prevent discharge.

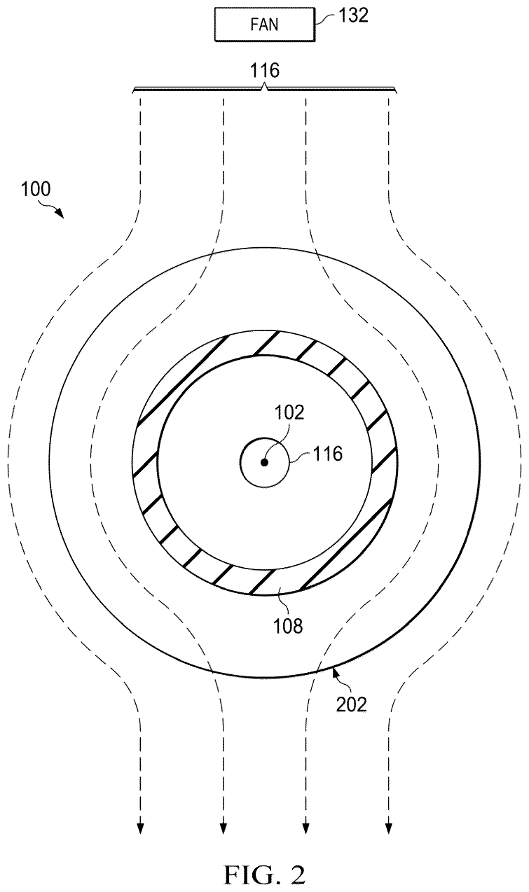

FIG. 2 is a cross-sectional view along the propagation direction of the electron beam (x-y plane) of the air-cooled depressed collector 100, in accordance with some embodiments of the present invention. As shown, FIG. 2 illustrates the electron beam 102, the electron beam path 116 (formed by the opening of the gateway 116, the opening of the serial electrode receptors 124 and the opening of the terminal electrode forward receptor 126), the insulator body 108, and the outer perimeter 202 of the serial electrode thermal fins 122, terminal electrode thermal fin 128 and/or heat sink thermal fins 112. As shown, the fan 132 (or other airflow generator) may generate airflow 116 to circulate around the air-cooled depressed collector 100, including between the serial electrode thermal fins 122, terminal electrode thermal fin 128 and heat sink thermal fins 112. Although FIG. 2 shows the design to include a circular geometries, other geometries are also possible.

Airflow 116 may be directed over the circumference of the electrodes 106/108 to maximize air flow exposure. Cross-flow can also be employed with the fin geometry optimized for airflow in that direction.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

The foregoing description of the preferred embodiments of the present invention is by way of example only, and other variations and modifications of the above-described embodiments and methods are possible in light of the foregoing teaching. The embodiments described herein are not intended to be exhaustive or limiting. The present invention is limited only by the following claims.

1. A depressed collector, comprising:
an insulator body;
a plurality of serial electrodes, each serial electrode having a serial electrode receptor portion inside the insulator body and having a serial electrode thermal fin portion passing through and extending outside the insulator body; and
a terminal electrode having a terminal electrode receptor portion inside the insulator body and having a terminal electrode thermal fin portion passing through and extending outside the insulator body.

2. The depressed collector of claim 1, wherein the insulator body is made of ceramic material.

3. The depressed collector of claim 1, wherein the serial electrode thermal fin portion of each serial electrode of the plurality of serial electrodes has substantially identical dimensions.

4. The depressed collector of claim 3, wherein the terminal electrode thermal fin portion has substantially identical dimensions to the serial electrode thermal fin portion of each serial electrode.

5. The depressed collector of claim 1, wherein the serial electrode thermal fin portions of the plurality of serial electrodes have substantially identical spacing.

6. The depressed collector of claim 5, wherein the terminal electrode thermal fin portion has the substantially identical spacing from one of the serial electrode thermal fin portions of the plurality of serial electrodes.

7. The depressed collector of claim 1, wherein the terminal electrode receptor portion is a terminal electrode rear receptor portion and the terminal electrode further includes a terminal electrode forward receptor portion.

8. The depressed collector of claim 1, further comprising a heat sink attached to the terminal electrode.

9. The depressed collector of claim 8, wherein the heat sink has a heat sink surface mounted flush to a rear wall of the terminal electrode.

10. The depressed collector of claim 9, wherein the heat sink includes heat sink thermal fins extending outward.

11. The depressed collector of claim 10, wherein the heat sink thermal fins have substantially identical geometry.

12. The depressed collector of claim 10, wherein the heat sink thermal fins have substantially identical spacing.

13. The depressed collector of claim 1, further comprising a gateway coupled to the insulator body and having a gateway opening to allow an electron beam from an interaction structure to enter the depressed collector.

14. The depressed collector of claim 13, wherein the gateway is maintained at ground potential, and each of the plurality of serial electrodes and the terminal electrode is maintained at a high voltage potential.

15. The depressed collector of claim 14, wherein the plurality of serial electrodes and the terminal electrode are maintained at respectively increasing voltage potentials.

16. The depressed collector of claim 1, wherein the insulator body, the plurality of serial electrodes and the terminal electrode assist in forming an enclosure.

17. The depressed collector of claim 16, wherein the enclosure maintains a vacuum environment.

18. The depressed collector of claim 1, wherein the plurality of serial electrodes and the terminal electrode comprise metal.

19. The depressed collector of claim 1, wherein each of the plurality of serial electrodes and the terminal electrode is maintained at a high voltage potential, and wherein the plurality of serial electrodes and the terminal electrode are maintained at a distance from a ground plane to avoid ionization.

20. The depressed collector of claim 1, wherein at least one serial electrode of the plurality of serial electrodes includes a plurality of thermal fin portions extending outside the insulator body.

21. A method comprising:
providing a depressed collector including
an insulator body;
a plurality of serial electrodes, each serial electrode having a serial electrode receptor portion inside the insulator body and having a serial electrode thermal fin portion passing through and extending outside the insulator body; and
a terminal electrode having a terminal electrode receptor portion inside the insulator body and having a terminal electrode thermal fin portion passing through and extending outside the insulator body; and
passing a gas over the serial electrode thermal fin portions of the plurality of serial electrodes.

22. The method of claim 21, wherein the depressed collector further includes a heat sink attached to the terminal electrode, the heat sink having heat sink thermal fins extending outward, and wherein the passing the gas over the serial electrode thermal fin portions of the plurality of serial electrodes includes passing the gas over the heat sink thermal fins.

23. The method of claim 21, wherein the gas is air.

24. The method of claim 21, wherein each of the plurality of serial electrodes and the terminal electrode is maintained at a high voltage potential, and wherein the plurality of serial electrodes and the terminal electrode are maintained at a distance from a ground plane to avoid ionization.
